(19) United States
(12) Patent Application Publication
(10) Pub. No.: US 2005/0250272 A1
(43) Pub. Date: Nov. 10, 2005

(54) Biosensor performance enhancement features and designs

(76) Inventor: James W. Holm-Kennedy, Honolulu, HI (US)

Correspondence Address: JAMES C. WRAY, 1493 CHAIN BRIDGE ROAD, SUITE 300, MCLEAN, VA, 22101, US

(21) Appl. No.: 11/120,649

(22) Filed: May 3, 2005

Related U.S. Application Data
(60) Provisional application No. 60/568,297, filed on May 3, 2004.

(51) Int. Cl. H01L 21/336; H01L 21/8234; H01L 21/8238

(52) U.S. Cl. 438/197

(57) ABSTRACT

Isolation of semiconductor based biosensors is described. The present invention is directed to prevention of undesirable influences including, but not limited to, chip leakage current. Several forms of sensor isolation and other protective means affect protection from adverse chip influences. The effect of biochemical attachment outside the sensor active region may have adverse effects on sensor performance. This potential problem is averted using protective design features.

This application claims the benefit of U.S. Provisional Application No. 60/568,297, filed May 3, 2004, which is hereby incorporated by reference in its entirety.

### BACKGROUND OF THE INVENTION

Electronic devices fabricated with integrated circuit (IC) technologies require biases and conduits to external contacts, where such biases are applied or measured and current is conducted into and out of the electronic devices.

A conductor passing over an underlying substrate is isolated from the substrate by an oxide or insulator layer. The voltage of the interconnect line creates an electric field between the conducting interconnect line and the underlying substrate. If this electric field is sufficiently large, an accumulation or inversion layer may be formed. If an inversion layer forms, there is a depletion region separating the induced channel from the underlying semi-conducting substrate. If this junction is reverse biased, the underlying induced channel connects to the drain contact and the depletion region is then reverse biased. The reversed biased depletion region delivers current to the inversion channel. The current is conducted along the channel to the drain contact and adds to the drain current. As the drain voltage changes so does the recovered depletion leakage current contribution. As the drain voltage is increased, the amount of back bias on the induced junction is increased. The depletion related volume and the amount of thermally generated leakage current are also increased. Such leakage current, if blocking means are not provided, adds to the leakage current, creating a net increase in drain current and a drain voltage dependence of the drain current magnitude. The current contribution may be substantial even at zero drain voltage if the substrate channel is reverse biased by a substrate-applied voltage. Leakage current is acquired without a drain voltage applied as long as the drain to substrate voltage biases the induced depletion regions with the thermally generated leakage current.

While one solution is to increase the field oxide thickness, and this is the solution typically used by industry (thick field oxide), this solution is insufficient for the biosensor for several reasons. One reason is the desire to apply large reverse biases to the P drain and channel diode junction (with the underlying N-substrate). The arguments conceptually carry through for N-channel devices as well. P-Channel devices are used by way of example in this document since many biochemicals are negatively charged.

Some improvement may be achieved by making the surface N+ surrounding the sensor, if care is taken not to form a tunneling junction. However, this solution will also fail for sufficient drain to substrate reverse biases and for some biochemical attached charge conditions.

This problem is non-obvious since normal FET structures are isolated and the field oxide is designed not to invert the surface. Such inversion does not occur because a large reverse bias on the drain and channel region is normally not applied. For the biosensor, a large reverse bias is desirable at times because this can decrease the buried channel region and thus increases biosensor sensitivity or is used as a measurement parameter.

A second non-obvious situation arises for any field oxide thickness. If biochemicals attached to the field region of the IC chip, the electric field has the same value inside of the field oxide regardless of the field oxide thickness. For example, a heavy coating of negatively charged biochemicals induce a P-channel on the N-substrate surface and the attendant PN junction depletion region. Thus, by simply creating a sensor condition where the amount of charge attached to the field oxide surfaces surrounding the sensor is great enough to induce a channel (negative charges may induce a P-Channel), the problem of channel and depletion formation with attendant leakage current can occur. This situation is non-obvious since IC chips do not typically have such attached charges on the field oxide, and the field oxide thickness is considered the design feature that blocks inversion of the underlying substrate. Field oxide thickness is ineffective in the attached charge chase where the Gaussian field is strong enough to induce a channel connecting to the source or drain of the sensor.

Needs exist for enhanced biosensor performance and designs.

### SUMMARY OF THE INVENTION

The present invention may take several different forms to improve biosensor performance.

The first form is an increase in field oxide thickness. The field oxide is increased such that the difference between the substrate voltage and overlying drain and/or source conduit voltage creates an electric field across the field oxide that is lower than that needed to form an inversion layer and a pseudo PN junction.

Another form is to create P+ wells to isolate the sensor from the substrate. An epitaxial N layer is placed on a P substrate. This PN junction provides basic isolation of the sensor from the substrate. However, by placing P+ posts through the N epi layer, the N epi layer is isolated from the remainder of the substrate. A back bias exists between the P region and the portion of the N-well containing the sensor, in this example, a P-Channel device. Here the well is made as small are possible depending on the size of the actual sensor active region.

Another form is to create trench isolation. The sensor is surrounded and abutted with a trench cut deep into the semiconductor substrate. A substrate contact to the underlying N region permits the reverse bias to the back gate of the sensor channel with the attendant sensitivity and sensor parameter measuring features enabled. If there is some inversion of the N surface to become a P-channel, then current cannot flow around the channel between the source S and drain D. Leakage current is reduced substantially by trench isolation, whether caused by interconnects conduits or attached biochemical charge induction. The amount of induced junction leakage is kept negligible by maintaining minimum sensor, channel, source and drain inversionable areas.

Another form is mesa isolation. This form has the same function as the trench isolation but covers a much wider area.

Another form is conductive shield surface protection. A structure includes a sensor region fabricated on a semiconductor substrate and a conduction region protected by insulator materials and added to the remainder of the semiconductor substrate region to protect the surface from undesirable inversion or other phenomena. The conductive layer has a pre-selected bias applied with respect to the back gate bias. The pre-selected bias is chosen to keep the surface of the semiconductor under the interconnect conductors from displaying unwanted surface effects such as inversion, depletion and related unwanted leakage currents adversely contributing to the sensor signal.

An FET can acquire significant thermally generated depletion current contributions to a drain current in spite of using a very large field oxide. Field oxides are used to prevent such occurrences but it is clear that regardless of the field oxide thicknesses, such introduced erroneous drain currents may occur. The bio charge induced channel linked to the drain contact and leakage current generating depletion regions is completely independent of field oxide thickness. The field oxide approach of conventional IC chips is not adequate for certain conditions of the Silicon biosensing platform.

These and further and other objects and features of the invention are apparent in the disclosure, which includes the above and ongoing written specification, with the drawings.

### BRIEF DESCRIPTION OF THE DRAWINGS

FIG. 1A shows sensor isolation where the sensor is electronically isolated from the rest of the chip by the P⁺ posts.

FIG. 1B is a top view of the sensor isolation shown in FIG. 1A.

FIG. 2A shows sensor isolation where trenches are provided to isolate the sensor region electronically.

FIG. 2B shows a sensor with trench isolation.

FIG. 3 shows mesa isolation.

FIG. 4A shows a drain interconnect induced junction leakage current.

FIG. 4B shows channels induced by biochemical ions above a field oxide.

FIG. 5 shows total sensor drain current comparison.

FIG. 6A shows a conductive protection layer.

FIG. 6B shows a top view of a protective conductor.

### DETAILED DESCRIPTION OF THE PREFERRED EMBODIMENTS

The present invention may take several different forms to improve biosensor performance. The first form is an increase in field oxide thickness. The field oxide is increased such that the difference between the substrate voltage and overlying drain and/or source conduit voltage creates an electric field across the field oxide that is lower than that needed to form an inversion layer and a pseudo PN junction.

Another form of improvement is to create P+ wells 13 to isolate the sensor from the substrate 17. An epitaxial N layer 19 is placed on a P substrate 17. A PN junction 21 provides basic isolation of the sensor from the substrate. However, by placing P+ posts 13 through the N epi layer 19, the N epi layer 19 is isolated from the remainder of the substrate. A back bias exists between the P region and the portion of the N-well containing the sensor, in this example, a P-Channel device. Here the well is made as small are possible depending on the size of the actual sensor active region.

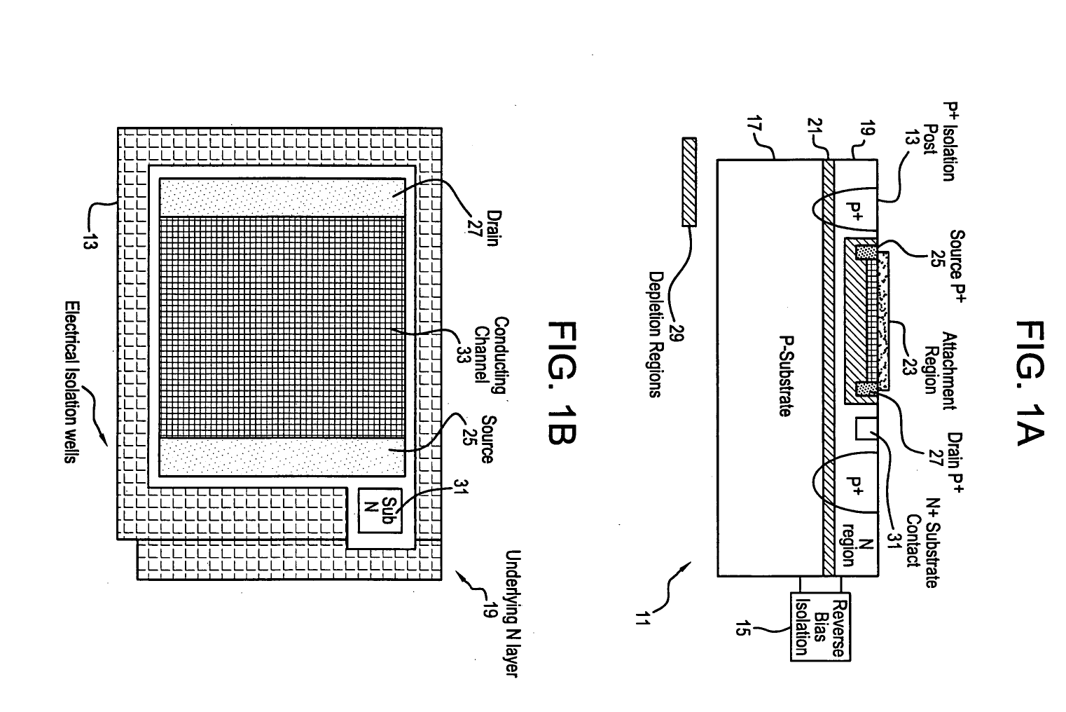

FIG. 1A shows sensor isolation where the sensor is electronically isolated from the rest of a chip 11 by P⁺ posts 13. Reverse bias 15 of the appropriate junction, as indicated, provides isolation. An attachment region 23 includes a source P+ 25 and a drain P+ 7. Depletion regions 29 are indicated with diagonal lines. An N+substrate contact 31 is located within the P+ isolation posts 13. A conducting channel 33 runs between the source 25 and the drain 27.

FIG. 1B is a top view of the sensor isolation shown in FIG. 1A. The diffused P⁺ post 13 isolates the region of the sensor. Direct contact with the channel region 33 cannot occur without shorting the channel region.

Another form of improvement is to create trench isolation. The sensor is surrounded and abutted with a trench 35 cut deep into the semiconductor substrate 17. A substrate contact 31 to the underlying N region permits the reverse bias to the back gate of the sensor channel with the attendant sensitivity and sensor parameter measuring features enabled. If there is some inversion of the N surface to become a P-channel, then current cannot flow around the channel between the source S and drain D. Leakage current is reduced substantially by trench isolation, whether caused by interconnects conduits or attached biochemical charge induction. The amount of induced junction leakage is kept negligible by maintaining minimum sensor, channel, source and drain inversionable areas.

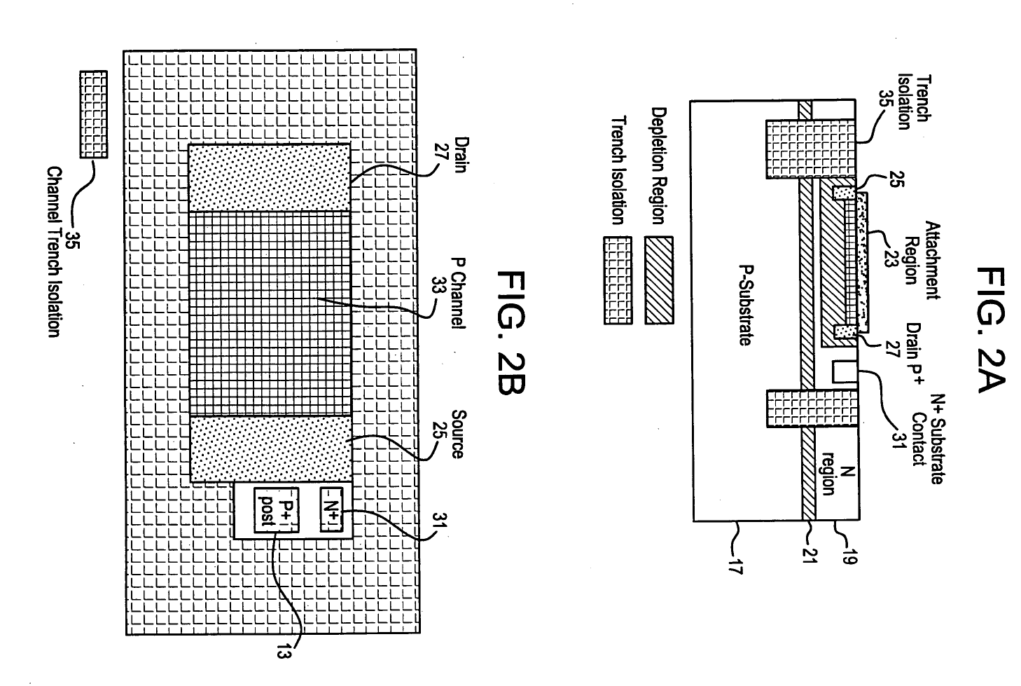

FIG. 2A shows sensor isolation where trenches 35 are provided to isolate the sensor region electronically.

FIG. 2B shows a sensor with trench isolation. The trench isolation surrounds the biosensor. The N+ back gate bias contact to the N-epi or implanted layer is shown. A P+ post 13 going through the N layer 19 to the underlying P substrate 17 is used to back bias the PN (epi/substrate) layer for further isolation (back biased). This approach is better than the diffused isolation P⁺ region. There is no shorting around the channel via any induced P channel region. Surfaces are treated to minimize surface recombination.

Another form of improvement is mesa isolation. This form has the same function as the trench isolation but covers a much wider area.

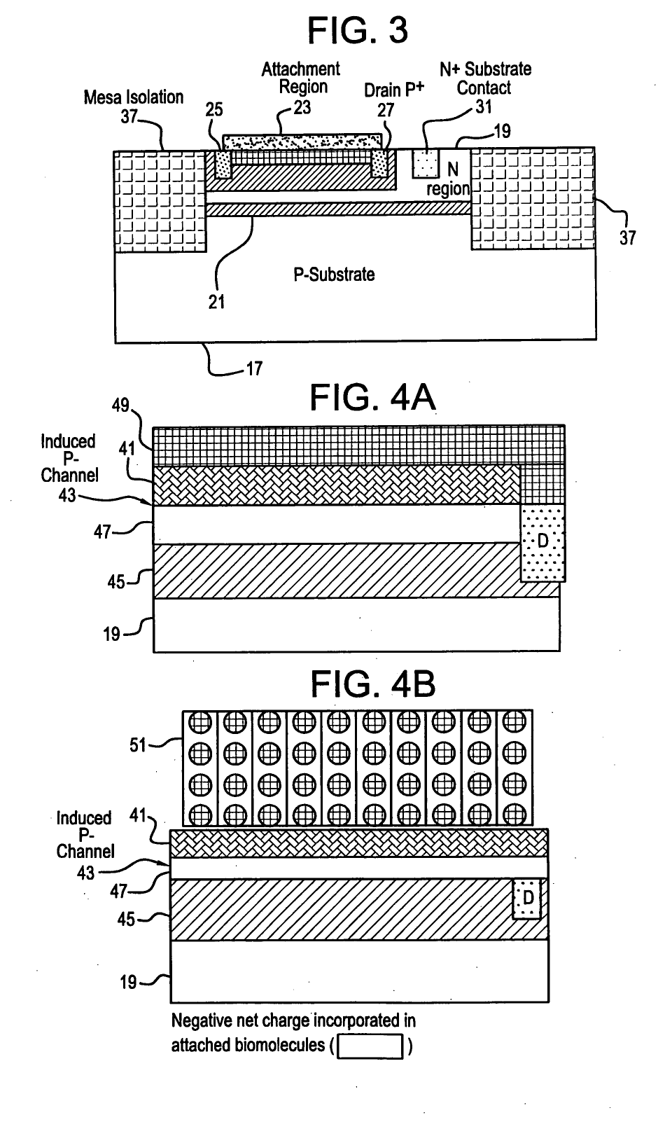

FIG. 3 shows mesa isolation 37. The sensor FET region is isolated from the remainder of the N region by etching a mesa around the sensor.

These methods may be used individually or in combination.

FIGS. 4A and 4B illustrate the problems with induced junction leakage currents adding to the drain current of the sensor and dependent upon the drain voltage value.

FIG. 4A shows a drain interconnect induced junction leakage current. The bias connection via a conductor over the field oxide 41 induces an inversion layer and/or depletion region 45 beneath the field oxide 41. The depletion region has a leakage current 43 that accumulates over the entire interconnect conductor region and delivers the accumulation to the FET drain contact. The higher the drain voltage the larger the depletion region. The difference between the substrate bias (back gate FET bias) and the drain bias voltage determines the magnitude of the depletion region. Once the inversion layer is formed, the drain then provides contact to the inversion region and the bias depletes from the channel into the substrate. A drain connection conductor 49 is above the field oxide.

FIG. 4B shows channels induced by biochemical ions 51 above a field oxide 41. In this example the attached biochemical molecules are negatively charged and attach to the surface of the field oxide. The charge induces an electric field through the field oxide 41 creating a P-channel 43 at the semiconductor surface and a resulting pseudo junction. The depletion region of the junction adds leakage current to the drain current 45, thus introducing an error in sensor measured current. The field oxide thickness does not affect this particular biochemical charge induced substrate pseudo PN junction and attendant leakage current 47. The substrate bias then biases the drain and pseudo junction depletion regions and both can contribute leakage current to the drain. Because of the usual very large field oxide regions such induced junction contributions to the drain current may be substantial.

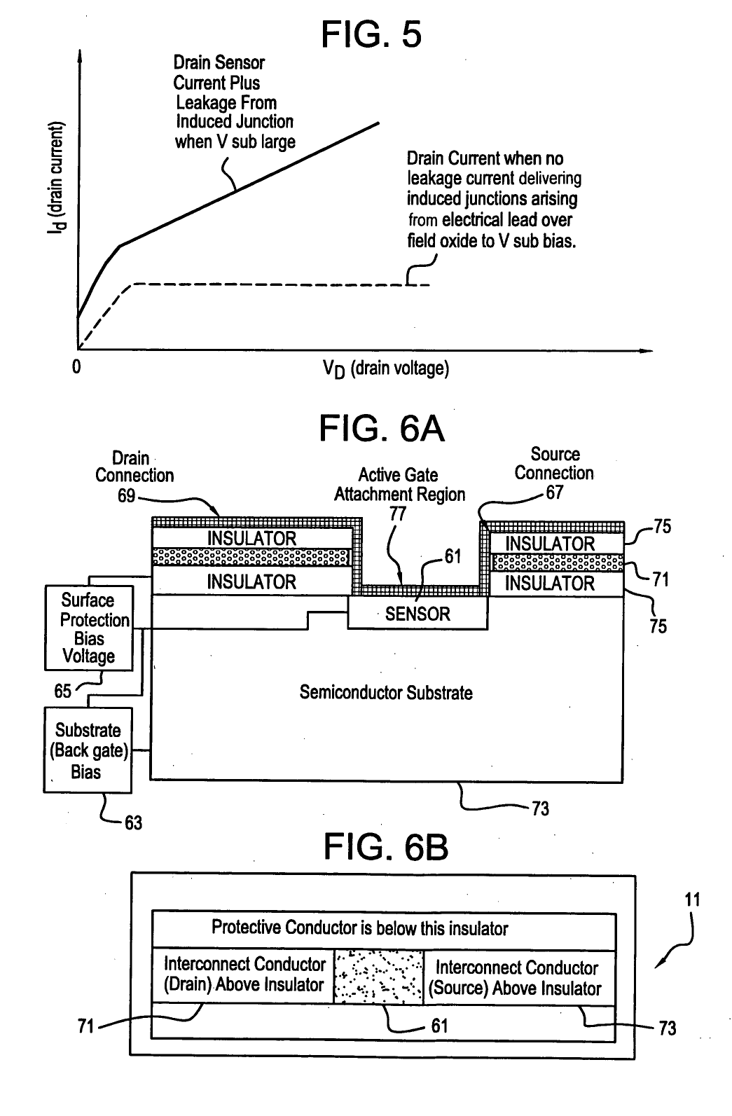

FIG. 5 shows total sensor drain current comparison. As the drain voltage changes so does the recovered depletion leakage current contribution. The drain current may be influenced by leakage current from an induced junction under the field oxide arising from the difference in the interconnect or drain voltage and the substrate voltage V_{sub}. Once formed, as the drain voltage increases, the amount of induced junction leakage current increases, as shown by the solid line. If the sensor is isolated from such induced junctions, then the leakage current is blocked and the drain current is normal as represented by the dotted line. It is noted that biochemicals can induce such inversion leading to leakage current. Isolation is achieved by the methods described in the present invention.

Another form of improvement is conductive shield surface protection. A structure includes a sensor region fabricated on a semiconductor substrate and a conduction region protected by insulator materials and added to the remainder of the semiconductor substrate region to protect the surface from undesirable inversion or other phenomena. The conductive layer has a pre-selected bias applied with respect to the back gate bias. The pre-selected bias is chosen to keep the surface of the semiconductor under the interconnect conductors from displaying unwanted surface effects such as inversion, depletion and related unwanted leakage currents adversely contributing to the sensor signal.

FIG. 6A shows a conductive protection layer 71. A conductive region 71 is layered above a semiconductor 73 outside of the sensor area 61 and between insulation layers 75. This region 61 is biased 65 with the same voltage as the back gate bias 63. In this manner the surface is not inverted outside the sensor region 61 and undesirable leakage current from a bulk inverted region does not occur. The conductive layer may be used with device having other forms of isolation, such as trench isolation, or the conductive layer may provide protection from unwanted leakage current measurement error introduction without other sensor isolation means. An active gate attachment region 77 is above the sensor 61.

FIG. 6B shows a top view of a protective conductor. The conductor 71, active sensor 61 and interconnect regions of the sensor chip 11 are schematically represented. The insulator between the protective conductive region and the interconnect conductors to a source 67 and drain 69 are not shown.

A partial list of these applications target molecule classes are listed in Table I by way of example. Table I is a partial list of a wide variety of chemicals that can be targeted or sensed with the performance improved biosensors. The term “receptor” is used in the most general sense. A chemical has an affinity for another chemical, a target chemical. Generally, that affinity is selective and specific to the target chemical. Antibodies are one example, nerve receptors another, drug receptors another, oligos are others.

Applications of the Si based biosensor platform are described in general applications regimes, by way of example, by the list provided in Table II.

While the invention has been described with reference to specific embodiments, modifications and variations of the invention may be constructed without departing from the scope of the invention.

TABLE I
Partial List of Chemical Targets

| | | | |
|---|---|---|---|
| Nucleic Acids | Oligos | Viruses | Acids |
| | c-DNA | Bacteria and it | Bases |
| | | component parts | |
| | | such as epitopes, | |
| | | membranes, | |
| | | proteins, Etc. | |
| | RNA | Cells (all kinds) | Chemicals |
| | | | affecting cell |
| | | | function and |
| | | | body function |
| | DNA | Membranes | Isoelectric |
| | | | Molecules |
| | | | (conditions) |
| | Other | Receptors | pH and pH |
| | | | influenced |
| | | | molecules |
| Antibodies | | Proteins | Ions |
| Enzymes | | Hormones | Toxins |
| BioDefense Agents | | Salts and Salt | Buffering Agents |
| | | Concentrations | |
| Pain Receptors | | Insecticides | Chemical Agents |
| Explosives | | Water Quality | Pb, Hg, and other |
| | | Monitoring | hazardous metals |
| Prions | | Organic Chemicals | Inorganic Chemicals |
| Drugs | | Nerve Components | Organ Components |
| Signaling | | Surface Chemicals | Symbiotic |
| Chemicals | | | Chemicals |
| Buffering Solutions | | Gases | Liquids |
| (component and | | | |
| concentrations) | | | |
| Membranes | | IONS | Chemical Fractions |
| Other | | Insecticides | Aerosols |

TABLE II
A Partial List of Sensor Applications

| | | | |
|---|---|---|---|
| Drug sensitivity | Drug Efficacy | Medical Diagnostics | Cancer Diagnostics |
| Proteomics | Genetics | Toxic Analysis | Bio Defense |
| Plant Pathogen | Human Pathogen | Animal Pathogen | Bacteria Detection, |
| Sensing | Sensing | Sensing | Identification, |
| | | | Characterization and |
| | | | Measurement |
| Virus Detection, | Fundamental | Binding Strengths of | “Receptor” |
| Identification, | Biochemical | molecules | properties |
| Characterization | Measurements | (dissociation strengths | |
| | | and affinities) | |
| Chemical | Chemical Reaction | Multiple targets | Biochemical Load |
| Thermodynamic | Dynamics | simultaneously | |
| Parameters | | | |
| Cells | Cell chemicals | Cell Dynamics | Cell Division |
| Air Quality | Food Quality | Crop Diseases and | Water Quality |
| Monitoring | Monitoring and Safety | Safety | Monitoring and |
| | | | Safety |
| General | Chemical | Chemical | Nutrition Monitoring |
| Environmental | Contamination | Constituents | and Diagnostics |
| Monitoring | | | |
| Blood Banking | Public Heath | OSHA Chemical | Laboratory Safety |
| | Monitoring and | Monitoring | |
| | Diagnostics | | |
| Explosive Detection | Forensics | Chemical Properties | pH Measurement |
| and Identification | | (e.g., isoelectric | |
| | | point) | |
| Medical Technology | Materials Properties | Electronic Functions | Chemical Potential |
| | Including | | |
| | Thermodynamic | | |
| | Properties | | |

1. A biosensor performance enhancement comprising:
providing a P substrate,
providing an N region,
providing an oxide or insulation layer between the P substrate and N region,
attaching a source and a drain between a conducting channel on the N region at an attachment region,
providing isolation devices surrounding the attachment region.

2. The method of claim 1, wherein the oxide or insulation layer is thick.

3. The method of claim 2, wherein providing the thick oxide or insulation layer comprises creating a difference between substrate voltage and overlying drain and/or source conduit voltage such that an inversion layer and pseudo PN junction are formed.

4. The method of claim 2, further comprising providing a reverse bias isolation.

5. The method of claim 1, wherein the isolation devices create P+ wells for isolating the sensor from the substrate.

6. The method of claim 5, further comprising placing an epitaxal N layer on the P substrate.

7. The method of claim 5, wherein a back bias exists between the P substrate and the attachment region of the epitaxal N layer.

8. The method of claim 1, further comprising creating trench isolation.

9. The method of claim 8, wherein the creating trench isolation further comprises surrounding a sensor and abutting a sensor with a trench cut deep into the P substrate.

10. The method of claim 9, wherein maintaining minimum sensor, channel source and drain inversionable areas reduces induced junction leakage.

11. The method of claim 1, further comprising etching a mesa around the sensor for creating mesa isolation.

12. The method of claim 1, further comprising attaching biochemical charges to the substrate for inducing a junction leakage current.

13. The method of claim 1, further comprising providing a sensor region fabricated on a semiconductor substrate and providing a conduction region protected by insulators and added to the remainder of the semiconductor substrate region.

14. The apparatus of claim 13, wherein a conductive layer has a pre-selected bias applied with respect to the back gate bias.

15. A biosensor performance apparatus comprising:
a P substrate,
an N region,
an oxide or insulation layer between the P substrate and N region,
a source and a drain between a conducting channel on the N region on an attachment region,
one or more isolation devices surrounding the attachment region.

16. The apparatus of claim 15, wherein the oxide or insulation layer is thick, and wherein the thick oxide or insulation layer creates a difference between substrate voltage and overlying drain and/or source conduit voltage such that an inversion layer and pseudo PN junction are formed.

17. The apparatus of claim 15, wherein the one or more isolation devices are P+ wells for isolating the sensor from the substrate, and further comprising an epitaxal N layer on the P substrate.

18. The apparatus of claim 15, wherein the isolation devices are trench isolation, and wherein the trench isolation further comprises a trench cut deep into the P substrate surrounding and abutting a sensor.

19. The apparatus of claim 15, wherein the isolation devices are mesa isolation, and wherein a mesa is etched around the sensor.

20. The apparatus of claim 15, further comprising a sensor region fabricated on a semiconductor substrate and a conduction region protected by insulators and added to the remainder of the semiconductor substrate region.
